(19) United States
(12) Patent Application Publication
(10) Pub. No.: US 2025/0349661 A1
(43) Pub. Date: Nov. 13, 2025

(54) SEMICONDUCTOR PACKAGE INCLUDING A SUBSTRATE HAVING A TRENCH

(71) Applicant: SAMSUNG ELECTRONICS CO., LTD., SUWON-SI (KR)

(72) Inventors: Wansun Kim, Suwon-si (KR); Hojin Seo, Suwon-si (KR); Shlege Lee, Suwon-si (KR)

(21) Appl. No.: 19/029,018

(22) Filed: Jan. 17, 2025

(30) Foreign Application Priority Data
May 10, 2024 (KR) 10-2024-0062194

(51) Int. Cl. H01L 23/373; H01L 23/13; H01L 23/538; H01L 25/18

(52) U.S. Cl. CPC H01L 23/373; H01L 23/13; H01L 25/18; H01L 23/538

(57) ABSTRACT

A semiconductor package includes a substrate, a first semiconductor device disposed on the substrate, a second semiconductor device disposed on the substrate and spaced apart from the first semiconductor device in a horizontal direction, an upper trench formed in an upper surface of the substrate at a side of the second semiconductor device, a lower trench formed in a lower surface of the substrate, and a molding portion disposed in the upper trench.

### CROSS-REFERENCE TO RELATED APPLICATION

This application is based on and claims priority under 35 U.S.C. § 119 to Korean Patent Application No. 10-2024-0062194, filed on May 10, 2024, in the Korean Intellectual Property Office, the disclosure of which is incorporated by reference herein in its entirety.

### BACKGROUND

### 1. Technical Field

The inventive concept relates to a semiconductor package, and more particularly, to a semiconductor package including a plurality of semiconductor chips on a substrate having a trench.

### 2. Discussion of Related Art

Electronic apparatuses are becoming more compact and lighter with the development of the electronic industries and users' demands. As the electronic apparatuses become smaller and lighter, there is increased pressure on semiconductor packages used therein to also becoming smaller and lighter. In addition, reliability, performance, and capacity need to be ensured for the semiconductor packages. Accordingly, a semiconductor package including a plurality of semiconductor chips has been proposed. For example, a method of mounting several types of semiconductor chips side-by-side on a single package substrate, or stacking semiconductor chips or packages on a single package substrate may be used.

### SUMMARY

The inventive concept provides a semiconductor package having improved reliability and including a plurality of semiconductor chips arranged side-by-side.

The inventive concept also provides a semiconductor package with controlled warpage of a substrate on which a plurality of semiconductor chips are mounted asymmetrically.

In addition, the objects of the inventive concept are not limited to the aforementioned object, but other objects not described herein will be clearly understood by those skilled in the art from the following description.

According to an aspect of the inventive concept, there is provided a semiconductor package including a substrate, a first semiconductor device disposed on the substrate, a second semiconductor device disposed on the substrate and spaced apart from the first semiconductor device in a horizontal direction, an upper trench formed in an upper surface of the substrate at a side of the second semiconductor device, a lower trench formed in a lower surface of the substrate, and a molding portion disposed in the upper trench.

According to another aspect of the inventive concept, there is provided a semiconductor package including a substrate, a first semiconductor device disposed on the substrate, a second semiconductor device disposed on the substrate and spaced apart from the first semiconductor device in a horizontal direction, an upper trench formed in an upper surface of the substrate at a side of the second semiconductor device, a lower trench formed in a lower surface of the substrate, and a molding portion disposed in the lower trench.

According to another aspect of the inventive concept, there is provided a semiconductor package including a substrate, a plurality of external connection terminals arranged on a lower surface of the substrate, a passive device disposed on the lower surface of the substrate, a first semiconductor device disposed on the substrate, a second semiconductor device disposed on the substrate and spaced apart from the first semiconductor device in a horizontal direction, an upper trench formed in an upper surface of the substrate, a lower trench having a shape symmetrical to the upper trench and formed in the lower surface of the substrate to overlap the upper trench in a vertical direction and not to overlap the plurality of external connection terminals, and a molding portion configured to fill an inner space of the upper trench and including a material having a coefficient of thermal expansion and a modulus of elasticity greater than a coefficient of thermal expansion and a modulus of elasticity of the substrate, wherein the upper trench is adjacent to a side surface of the second semiconductor device, is parallel to the side surface of the second semiconductor device, and extends longer than a length of the side surface of the second semiconductor device, and a depth of the upper trench and a depth of the lower trench each are less than or equal to ⅓ of a thickness of the substrate.

### BRIEF DESCRIPTION OF THE DRAWINGS

Embodiments will be more clearly understood from the following detailed description taken in conjunction with the accompanying drawings in which:

FIG. 1 is a plan view schematically showing a semiconductor package according to an embodiment;

FIG. 2 is a cross-sectional view of the semiconductor package taken along line I-I′ of FIG. 1;

FIG. 3 is a plan view schematically showing a semiconductor package according to an embodiment;

FIG. 4 is a cross-sectional view of the semiconductor package taken along line II-II′ of FIG. 3;

FIG. 5 is a plan view schematically showing a semiconductor package according to an embodiment;

FIG. 6 is a cross-sectional view of the semiconductor package taken along line III-III′ of FIG. 5;

FIG. 7 is a plan view schematically showing a semiconductor package according to an embodiment;

FIG. 8 is a cross-sectional view of the semiconductor package taken along line IV-IV′ of FIG. 7;

FIG. 9 is a plan view schematically showing a semiconductor package according to an embodiment;

FIG. 10 is a cross-sectional view of the semiconductor package taken along line V-V′ of FIG. 9;

FIG. 11 is a plan view schematically showing a semiconductor package according to an embodiment;

FIG. 12 is a cross-sectional view of the semiconductor package taken along line VI-VI′ of FIG. 11;

FIG. 13 is a plan view schematically showing a semiconductor package according to an embodiment;

FIG. 14A and FIG. 14B are cross-sectional views schematically showing semiconductor packages according to an embodiment;

FIG. 15 is a plan view schematically showing a semiconductor package according to an embodiment;

FIG. 16 is a plan view schematically showing a semiconductor package according to an embodiment; and

FIG. 17A, FIG. 17B, FIG. 17C, and FIG. 17D are diagrams showing a process of manufacturing a semiconductor package, according to an embodiment.

### DETAILED DESCRIPTION

The following detailed description is provided to assist the reader in gaining a comprehensive understanding of methods, apparatuses, and/or systems described herein. However, various changes, modifications, and equivalents of methods, apparatuses, and/or systems described herein will be apparent after an understanding of the disclosure of this application. For example, the sequences of operations described herein are examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided to illustrate some of the many possible ways of implementing methods, apparatuses, and/or systems described herein that will be apparent after an understanding of the disclosure of this application.

Hereinafter, embodiments are described in detail with reference to the accompanying drawings. The same reference numerals are given to the same elements in the drawings, and repeated descriptions thereof may be omitted or simplified.

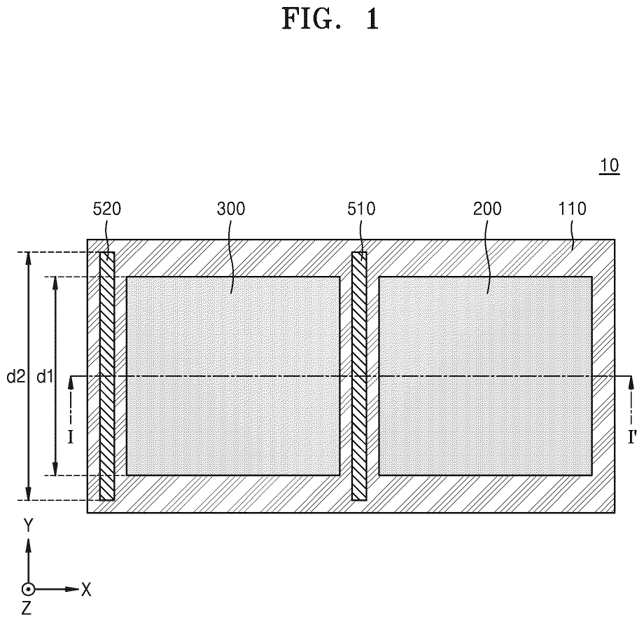

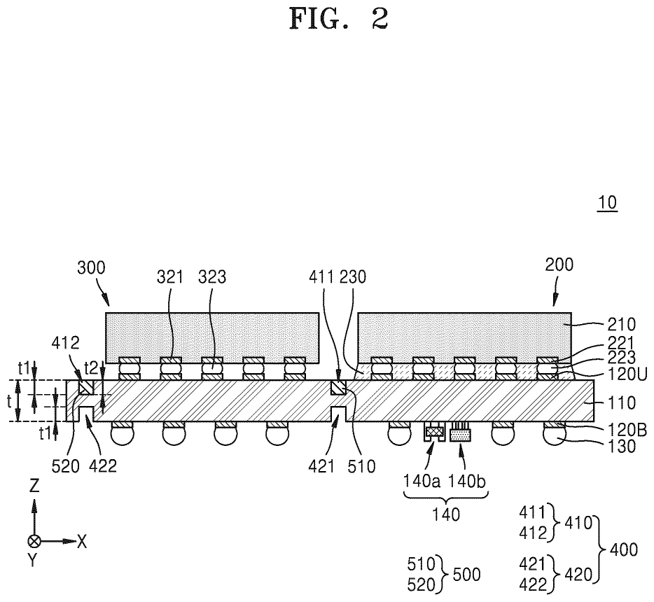

FIG. 1 is a plan view schematically showing a semiconductor package 10 according to an embodiment. FIG. 2 is a cross-sectional view of the semiconductor package 10 taken along line I-I′ of FIG. 1.

Referring to FIG. 1 and FIG. 2, the semiconductor package 10 according to an embodiment may include a substrate 110, a first semiconductor device 200, a second semiconductor device 300, a trench 400, and a molding portion 500.

As used herein, a horizontal plane represents an X-Y plane. Also, a first horizontal direction represents an X direction and a second horizontal direction represents a Y direction. A vertical direction represents a direction perpendicular to the X-Y plane, and the vertical direction represents a Z direction. The vertical direction may be perpendicular to the first horizontal direction, and at the same time, the vertical direction may be perpendicular to the second horizontal direction.

The semiconductor package 10 according to an embodiment may include the substrate 110. The substrate 110 may include a printed circuit board (PCB). The PCB may have wires formed therein or thereon. A lower connection pad 120B may be disposed on the lower surface of the substrate 110. A plurality of external connection terminals 130 may be provided on the lower connection pad 120B. An upper connection pad 120U may be disposed on the upper surface of the substrate 110.

A passive device 140 may be further provided on the lower surface of the substrate 110. According to embodiments, the passive device 140 may be disposed on the upper surface of the substrate 110 or inside of the substrate 110. The passive device 140 may include a two-terminal element, such as a resistor, an inductor, or a capacitor. In the semiconductor package 10 according to an embodiment, the passive device 140 may include a multi-layer ceramic capacitor (MLCC) 140a and an Si-capacitor 140b. The passive device 140 may be electrically connected to another component.

The first semiconductor device 200 may be disposed on the upper surface of the substrate 110. The first semiconductor device 200 may be disposed on the substrate 110 while being biased to a side thereof in the first horizontal direction (the X direction). For example, as illustrated in FIG. 1, the first semiconductor device 200 may be disposed on the substrate 110 while being biased to the right in the first horizontal direction (the X direction).

The first semiconductor device 200 may include a first semiconductor substrate 210, a first chip connection pad 221, and a first connection terminal 223. The first chip connection pad 221 may be provided in plurality. The first connection terminal 223 may be provided in plurality.

The first semiconductor device 200 may include the first semiconductor substrate 210, which has an active surface on which semiconductor devices may be formed, and a plurality of first chip connection pads 221, which may be arranged on the active surface of the first semiconductor substrate 210.

The first semiconductor substrate 210 may include, for example, a semiconductor material, such as silicon (Si). Also, the first semiconductor substrate 210 may include semiconductor elements, such as germanium (Ge), or compound semiconductors, such as silicon carbide (SiC), gallium arsenide (GaAs), indium arsenide (InAs), and indium phosphide (InP). The first semiconductor substrate 210 may include a conductive region, for example, a well doped with impurities. The first semiconductor substrate 210 may have other device isolation structures, such as a shallow trench isolation (STI) structure.

A semiconductor device including a plurality of other types of individual devices may be formed on the active surface of the first semiconductor substrate 210. The plurality of individual devices may include other microelectronic devices, for example, metal-oxide-semiconductor field effect transistors (MOSFET), such as complementary metal-oxide-semiconductor (CMOS) transistors, system large scale integration (LSI), image sensors, such as CMOS imaging sensors (CIS), micro-electro-mechanical systems (MEMS), active devices, or passive devices.

The plurality of individual devices may be electrically connected to the conductive region of the first semiconductor substrate 210. The semiconductor device may further include a conductive wire or a conductive plug, which electrically connects at least two of the plurality of individual devices to each other or electrically connects the plurality of individual devices to the conductive region of the first semiconductor substrate 210. Also, the plurality of individual devices may be electrically separated from other neighboring individual devices by an insulating film.

According to embodiments, the first semiconductor device 200 may include at least one semiconductor chip, and the semiconductor chip may include a logic chip. For example, the first semiconductor device 200 may include an application processor (AP), such as a central processing unit (CPU), a graphics processing unit (GPU), a field-programmable gate array (FPGA), a digital signal processor, a cryptographic processor, a microprocessor, and a microcontroller. For example, the first semiconductor device 200 may include a logic chip, such as an analog-digital converter (ADC) and an application-specific IC (ASIC). However, embodiments are not limited thereto, and the first semiconductor device 200 may include memory chips, such as volatile memory (e.g., dynamic random-access memory (DRAM)) or non-volatile memory (e.g., read only memory (ROM) or flash memory). The first semiconductor device 200 may include a system on chip (SoC). Also, the first semiconductor device 200 may be constructed by combining the components described above.

In some embodiments, the first semiconductor device 200 may be mounted on the substrate 110. For example, the first semiconductor device 200 may be mounted on the substrate 110 using a flip chip bonding method. The first semiconductor device 200 may include a plurality of first chip connection pads 221 on the lower surface thereof. The first semiconductor device 200 may include first connection terminals 223 respectively connected to the plurality of first chip connection pads 221. For example, the first connection terminals 223 may be provided between some of upper connection pads 120U provided on the upper surface of the substrate 110 and the first chip connection pads 221 provided on the lower surface of the first semiconductor device 200. The first connection terminals 223 may electrically connect the substrate 110 to the first semiconductor device 200. For example, the first connection terminals 223 may include solder balls or micro bumps.

The semiconductor package 10 according to an embodiment may include a first underfill layer 230. The first underfill layer 230 may be formed in a space between the first semiconductor device 200 and the substrate 110 and may surround the first connection terminals 223. For example, the first underfill layer 230 may fill the space between the first semiconductor device 200 and the substrate 110 and may surround the first connection terminals 223. The first underfill layer 230 may include resin. For example, the first underfill layer 230 may be formed of epoxy resin by a capillary under-fill method. The first underfill layer 230 may be mixed with a filler, and the filler may include, for example, silica.

The planar area of the lower surface of the first underfill layer 230 in contact with the upper surface of the substrate 110 may be greater than the planar area of the upper surface of the first underfill layer 230 in contact with the lower surface of the first semiconductor device 200. In other words, the cross-section of the first underfill layer 230 as shown in FIG. 2 may have a width in the horizontal plane that may decrease with the distance from the substrate 110. For example, the cross-section of the first underfill layer 230 may have a tapered shape of which the horizontal width decreases with the distance from the substrate 110.

The second semiconductor device 300 and the first semiconductor device 200 may be arranged side-by-side on the upper surface of the substrate 110. For example, the second semiconductor device 300 may be disposed on the substrate 110 and spaced apart from the first semiconductor device 200 in the first horizontal direction (the X direction). According to embodiments, the second semiconductor device 300 may be provided in plurality, and the plurality of second semiconductor devices 300 may be spaced apart from each other in the horizontal direction (the X direction and/or the Y direction).

According to embodiments, the second semiconductor device 300 may include at least one semiconductor chip. For example, the second semiconductor device 300 may include, as memory chips, volatile memory chips, such as DRAM and static random-access memory (SRAM), or non-volatile memory chips, such as phase-change random access memory (PRAM), magnetoresistive random access memory (MRAM), ferroelectric random access memory (FeRAM), or resistive random access memory (RRAM). The plurality of memory chips may be stacked and provided in the second semiconductor device 300. For example, the second semiconductor device 300 may include a high bandwidth memory (HBM) package or a wire bonding memory package in which a plurality of the memory chips may be stacked. However, embodiments are not limited thereto, and the second semiconductor device 300 may include a logic chip, for example, an AP, such as a CPU, a GPU, an FPGA, a digital signal processor, a cryptographic processor, a microprocessor, or a microcontroller.

In some embodiments, the second semiconductor device 300 may include a semiconductor package. The second semiconductor device 300 may include a plurality of second chip connection pads 321 on the lower surface thereof. The second semiconductor device 300 may include second connection terminals 323 respectively connected to the plurality of second chip connection pads 321. The second connection terminals 323 may electrically connect the substrate 110 to the second semiconductor device 300. For example, the second connection terminals 323 may include solder balls or micro bumps.

In the semiconductor package 10 according to an embodiment, the second semiconductor device 300 may be mounted on the substrate 110 at a time different than a time when the first semiconductor device 200 may be mounted on the substrate 110. Accordingly, while manufacturing the semiconductor package 10, a process may proceed with the first semiconductor device 200 mounted on the substrate 110, before a time when the second semiconductor device 300 may be mounted on the substrate 110. As described herein, when the process is performed in a state in which only the first semiconductor device 200 is mounted on the substrate 110 among the two semiconductor devices to be arranged side-by-side, warpage of the substrate 110 may occur. In particular, when the size of the semiconductor package is large and the size of the chips placed on the substrate is restricted, it may be difficult to inhibit or prevent warpage of the substrate.

Warpage of the substrate may be a deviation from flatness. Warpage may be caused by an internal stress in the substrate 110 or semiconductor package 10. The warpage may be, for example, a concave or a convex flexing of the substrate 110 or semiconductor package 10.

The semiconductor package 10 according to an embodiment may include the trench 400 formed in the substrate 110 and the molding portion 500 formed in the trench 400. For example, the molding portion 500 may fill an inner space of the trench 400.

The trench 400 may include an upper trench 410 formed in the upper surface of the substrate 110 and a lower trench 420 formed in the lower surface of the substrate 110. The upper trench 410 may be formed in the upper surface of the substrate 110 at a side of the second semiconductor device 300. According to embodiments, the upper trench 410 may be formed in the substrate 110. The upper trench 410 may be spaced apart from the side of the second semiconductor device 300 and may extend parallel to the side thereof. For example, the upper trench 410 may be provided as a groove that may be recessed from the upper surface of the substrate 110 in the thickness direction of the substrate 110.

The lower trench 420 may have a shape symmetrical to the upper trench 410. For example, the lower trench 420 may be provided as a groove that may be recessed from the lower surface of the substrate 110 in the thickness direction of the substrate 110. The lower trench 420 may be formed in the lower surface of the substrate 110 and symmetrical to the upper trench 410. According to embodiments, the lower trench 420 may overlap the upper trench 410 in the vertical direction (the Z direction).

The molding portion 500 may be configured to fill the inner space of the upper trench 410 or the lower trench 420. The molding portion 500 may include a material having a coefficient of thermal expansion higher than that of the substrate 110. Also, the molding portion 500 may include a material having a modulus of elasticity higher than that of the substrate 110.

Referring to FIG. 1 and FIG. 2, the upper trench 410 may include a first upper portion 411 and a second upper portion 412, and the lower trench 420 may include a first lower portion 421 and a second lower portion 422.

The first upper portion 411 of the upper trench 410 (hereinafter, referred to as the first upper portion 411) may be provided between the first semiconductor device 200 and the second semiconductor device 300. The first upper portion 411 may be located close to a first side surface, adjacent to the first semiconductor device 200, among the side surfaces of the second semiconductor device 300. The first upper portion 411 may be spaced apart from the first side surface of the second semiconductor device 300 on the substrate 110 and may extend parallel to the first side surface thereof. For example, the first upper portion 411 may be spaced apart from the first side surface of the second semiconductor device 300 in the first horizontal direction (the X direction) and may extend in the second horizontal direction (the Y direction). According to embodiments, the first upper portion 411 may be formed in the substrate 110 so as not to overlap the first semiconductor device 200 and the second semiconductor device 300 in the vertical direction (the Z direction). For example, the first upper portion 411 may be formed in the substrate 110 and spaced apart from the first semiconductor device 200 and the second semiconductor device 300 in the vertical direction (the Z direction).

A length d2 of the first upper portion 411 may be greater than a length dl of the first side surface of the second semiconductor device 300. For example, the length d2 of the first upper portion 411 may extend longer than the length dl of the first side surface of the second semiconductor device 300. Accordingly, the first side surface of the second semiconductor device 300 may completely overlap the first upper portion 411 in the first horizontal direction (the X direction). Both ends of the first upper portion 411 may not overlap the first side surface of the second semiconductor device 300 in the first horizontal direction (the X direction).

The second upper portion 412 of the upper trench 410 (hereinafter, referred to as the second upper portion 412) may be located close to a second side surface, opposite to the first semiconductor device 200, among the side surfaces of the second semiconductor device 300. The second upper portion 412 may be spaced apart from the second side surface of the second semiconductor device 300 on the substrate 110 and may extend parallel to the second side surface thereof. For example, the second upper portion 412 may be spaced apart from the second side surface of the second semiconductor device 300 in the first horizontal direction (the X direction) and may extend in the second horizontal direction (the Y direction). The second upper portion 412 may be formed so as not to overlap the second semiconductor device 300 in the vertical direction (the Z direction). For example, second upper portion 412 may be spaced apart from the second semiconductor device 300 in the vertical direction (the Z direction).

A length d2 of the second upper portion 412 may be equal to the length d2 of the first upper portion 411 and greater than a length dl of the second side surface of the second semiconductor device 300. Accordingly, the second side surface of the second semiconductor device 300 may completely overlap the second upper portion 412 in the first horizontal direction (the X direction). Both ends of the second upper portion 412 may not overlap the second side surface of the second semiconductor device 300 in the first horizontal direction (the X direction).

The first lower portion 421 of the lower trench 420 (hereinafter, referred to as the first lower portion 421) and the second lower portion 422 of the lower trench 420 (hereinafter, referred to as the second lower portion 422) may be provided in the lower surface of the substrate 110 to face the first upper portion 411 and the second upper portion 412, respectively.

The first lower portion 421 may be formed symmetrically with the first upper portion 411 about the substrate 110. For example, the first upper portion 411 may have a shape recessed downward from the upper surface of the substrate 110 in the thickness direction of the substrate 110 and may extend in the second horizontal direction (the Y direction). Also, the first lower portion 421 may have a shape recessed upward from the lower surface of the substrate 110 in the thickness direction of the substrate 110 and may extend in the second horizontal direction (the Y direction). The first lower portion 421 may be formed in the lower surface of the substrate 110 so as not to overlap the plurality of external connection terminals 130. For example, the first lower portion 421 may be formed in the lower surface of the substrate 110 and spaced apart from the plurality of external connection terminals 130.

Similarly, the second lower portion 422 may be formed symmetrically with the second upper portion 412 about the substrate 110. The second upper portion 412 may have a shape recessed downward from the upper surface of the substrate 110 in the thickness direction of the substrate 110 and may extend in the second horizontal direction (the Y direction). Also, the second lower portion 422 may have a shape recessed upward from the lower surface of the substrate 110 in the thickness direction of the substrate 110 and may extend in the second horizontal direction (the Y direction). The second lower portion 422 may be formed in the lower surface of the substrate 110 so as not to overlap the plurality of external connection terminals 130. For example, the second lower portion 422 may be formed in the lower surface of the substrate 110 and spaced apart from the plurality of external connection terminals 130.

The upper trench 410 and the lower trench 420 may be separated from each other in the vertical direction (the Z direction). For example, the upper trench 410 and the lower trench 420, which may overlap in a plan view, may be separated from each other in the vertical direction (the Z direction) by a portion of the substrate 110.

A depth t1 of each of the upper trench 410 and the lower trench 420 may be less than or equal to ⅓ of the thickness t of the substrate 110. For example, the depth t1 of each of the first upper portion 411 and the first lower portion 421 is less than or equal to ⅓ of the thickness t of the substrate 110, and the substrate 110 may not be penetrated by the first upper portion 411 and the first lower portion 421. Similarly, a depth t1 of each of the second upper portion 412 and the second lower portion 422 is less than or equal to ⅓ of the thickness t of the substrate 110, and the substrate 110 may not be penetrated by the second upper portion 412 and the second lower portion 422.

According to an embodiment, the molding portion 500 may be formed in the upper trench 410. For example, the molding portion 500 may be formed in the upper trench 410 and may not be formed on another portion. For example, the molding portion 500 may be formed in the upper trench 410 and may not be formed in the lower trench 420. According to an embodiment, the molding portion 500 may fill the upper trench 410. For example, the molding portion 500 may fill the upper trench 410 and may not fill another portion. For example, the molding portion 500 may fill the upper trench 410 and may fill the lower trench 420. The molding portion 500 may include a first upper molding portion 510 and a second upper molding portion 520 applied to the first upper portion 411 and the second upper portion 412, respectively. A thickness t2 of each of the first upper molding portion 510 and the second upper molding portion 520 may be greater than or equal to the depth t1 of each of the first upper portion 411 and the second upper portion 412. FIG. 2 illustrates that the thickness t2 of each of the first and second upper molding portions 510 and 520 may be equal to the depth t1 of each of the first and second upper portions 411 and 412 of the upper trench 410, but embodiments are not limited thereto. The thickness t2 of each of the first and second upper molding portions 510 and 520 may be greater than the depth t1 of each of the first and second upper portions 411 and 412 of the upper trench 410, and the first and second upper molding portions 510 and 520 may protrude from the upper surface of the substrate 110.

The first upper molding portion 510 and the second upper molding portion 520 may each include a material having a coefficient of thermal expansion and a modulus of elasticity greater than those of the substrate 110. For example, the first upper molding portion 510 and the second upper molding portion 520 may each include a thermosetting resin such as an epoxy resin, a thermoplastic resin such as polyimide, or a resin formed by adding a reinforcing material such as an inorganic filler into the thermosetting resin or thermoplastic resin, and specifically, may include AJINOMOTO BUILD-UP FILM® (ABF), FR-4, or BT, but embodiments are not limited thereto. For example, the first upper molding portion 510 and the second upper molding portion 520 may include a molding material such as an epoxy mold compound (EMC) and a photosensitive material such as a photo imageable encapsulant (PIE). In some embodiments, the first upper molding portion 510 and the second upper molding portion 520 may partially include an insulating material, such as a silicon oxide film, a silicon nitride film, and a silicon oxynitride film.

In the semiconductor package 10 according to an embodiment, the first upper molding portion 510 and the second upper molding portion 520 may be formed in the first upper portion 411 and the second upper portion 412, respectively. For example, the first upper portion 411 and the second upper portion 412 may be filled with the first upper molding portion 510 and the second upper molding portion 520, respectively. Also, the first lower portion 421 and the second lower portion 422 may remain in the form of grooves in the substrate 110. In particular, the flexural rigidity may decrease on the lower surface of the substrate 110 in which the first lower portion 421 and the second lower portion 422 are formed. However, the flexural rigidity may increase on the upper surface of the substrate 110 in which the first upper molding portion 510 and the second upper molding portion 520, which may include an elastic material having high thermal expansion properties, are formed. Accordingly, the semiconductor package 10 may exhibit the effect of inhibiting or preventing warpage. For example, the semiconductor package 10 may exhibit the effect of controlling a concave warpage in which edge portions of the substrate 110 lift higher than a central portion thereof.

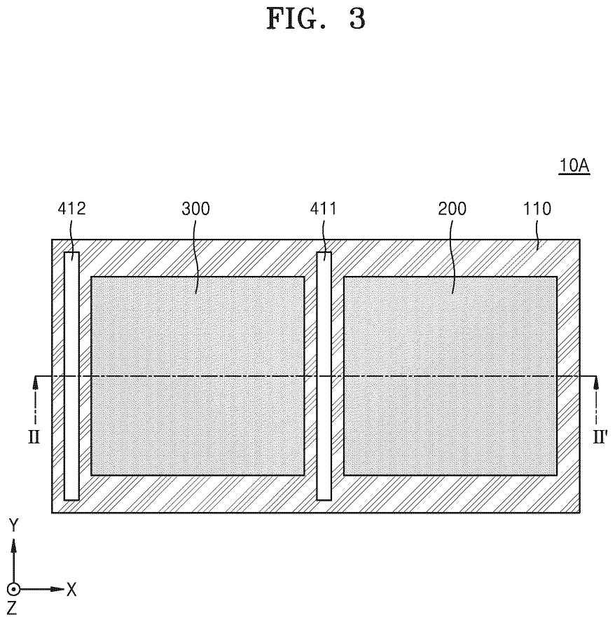

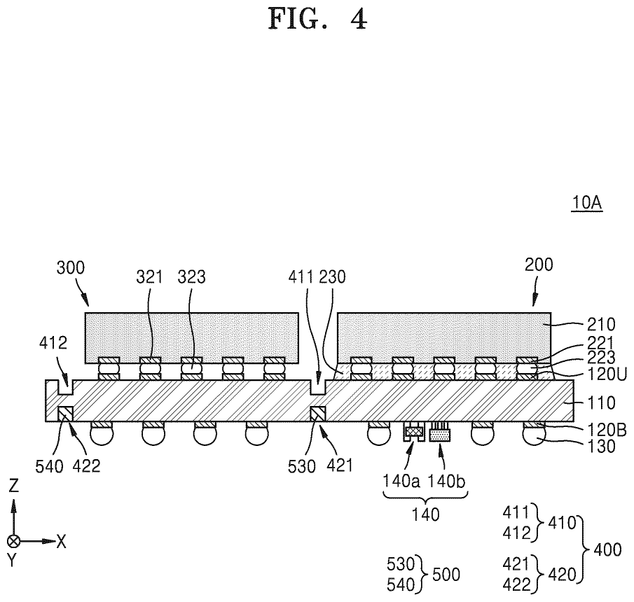

FIG. 3 is a plan view schematically showing a semiconductor package 10A according to an embodiment. FIG. 4 is a cross-sectional view of the semiconductor package 10A taken along line II-II′ of FIG. 3. Hereinafter, repeated descriptions of the semiconductor package 10 as those given with reference to FIG. 1 and FIG. 2 may be omitted or simplified.

Referring to FIG. 3 and FIG. 4, the semiconductor package 10A according to an embodiment may include a first lower molding portion 530 and a second lower molding portion 540. The first lower molding portion 530 and the second lower molding portion 540 may be formed in the lower trench 420. For example, the first lower molding portion 530 and a second lower molding portion 540 may fill the lower trench 420. The first lower molding portion 530 may be applied into the first lower portion 421 and fill the inner space thereof, and the second lower molding portion 540 may be applied into the second lower portion 422 and fill the inner space thereof.

The first lower molding portion 530 and the second lower molding portion 540 may each include a material having a coefficient of thermal expansion and a modulus of elasticity greater than those of the substrate 110. For example, the first lower molding portion 530 and the second lower molding portion 540 may each include a thermosetting resin such as an epoxy resin, a thermoplastic resin such as polyimide, or a resin formed by adding a reinforcing material such as an inorganic filler into the thermosetting resin or thermoplastic resin, and specifically, may include ABF, FR-4, BT, etc., but embodiments are not limited thereto. For example, the first lower molding portion 530 and the second lower molding portion 540 may include a molding material such as an EMC and a photosensitive material such as a PIE. In some embodiments, the first lower molding portion 530 and the second lower molding portion 540 may partially include an insulating material, such as a silicon oxide film, a silicon nitride film, or a silicon oxynitride film.

In the semiconductor package 10A according to an embodiment, the first lower molding portion 530 and the second lower molding portion 540 may be formed in the first lower portion 421 and the second lower portion 422, respectively. For example, the first lower portion 421 and the second lower portion 422 may be filled with the first lower molding portion 530 and the second lower molding portion 540, respectively. Also, the first upper portion 411 and the second upper portion 412 may remain in the form of grooves in the substrate 110. In particular, the flexural rigidity may decrease on the upper surface of the substrate 110 in which the first upper portion 411 and the second upper portion 412 are formed. However, the flexural rigidity may increase on the lower surface of the substrate 110 in which the first lower molding portion 530 and the second lower molding portion 540, which include an elastic material having high thermal expansion properties, are formed. Accordingly, the semiconductor package 10A may exhibit the effect of inhibiting or preventing warpage thereof. For example, the semiconductor package 10 may exhibit the effect of controlling a convex warpage in which a central portion of the substrate 110 may lift higher than edge portions thereof.

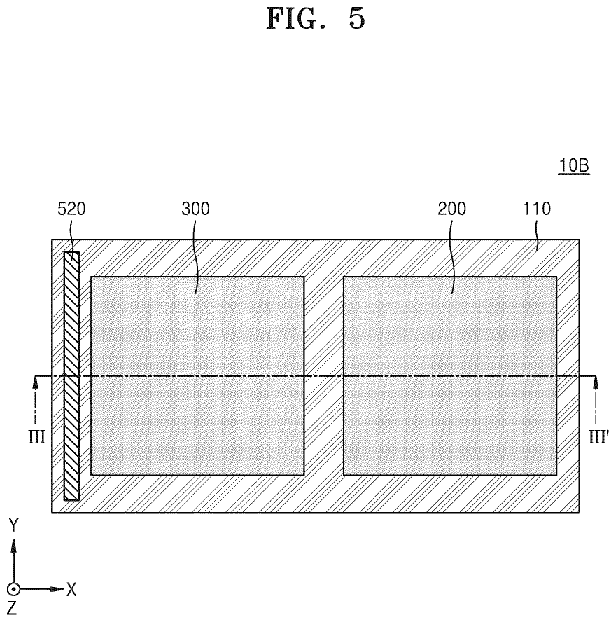

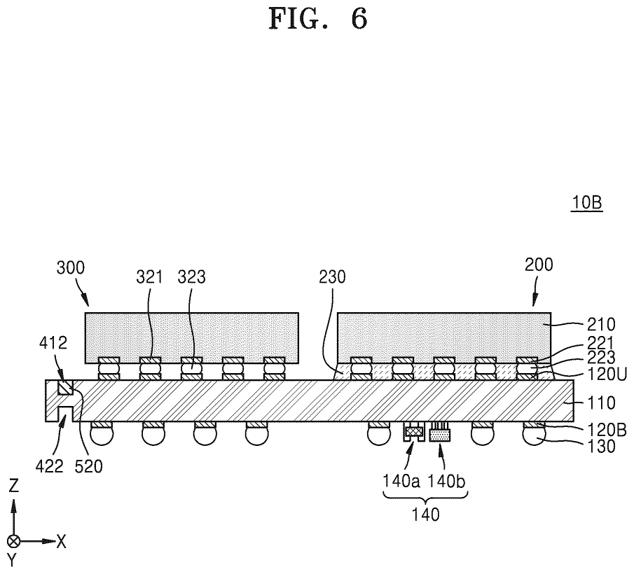

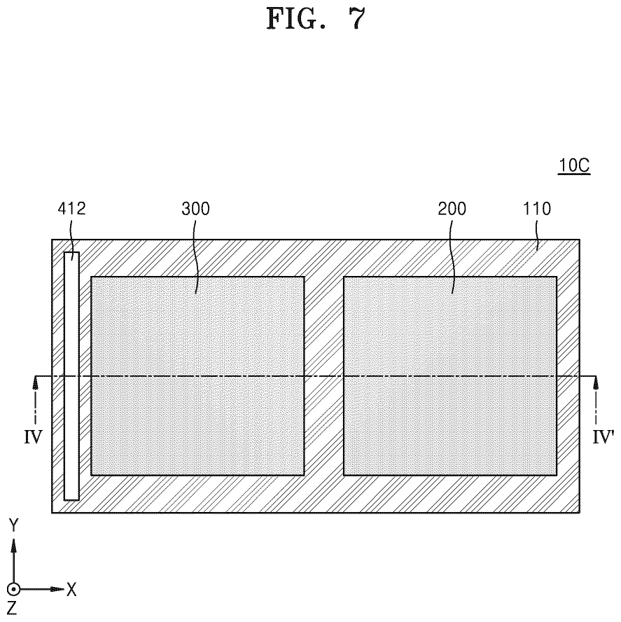

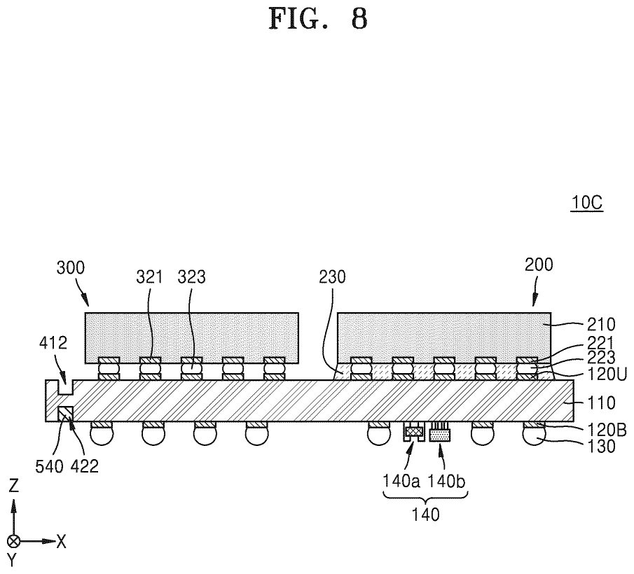

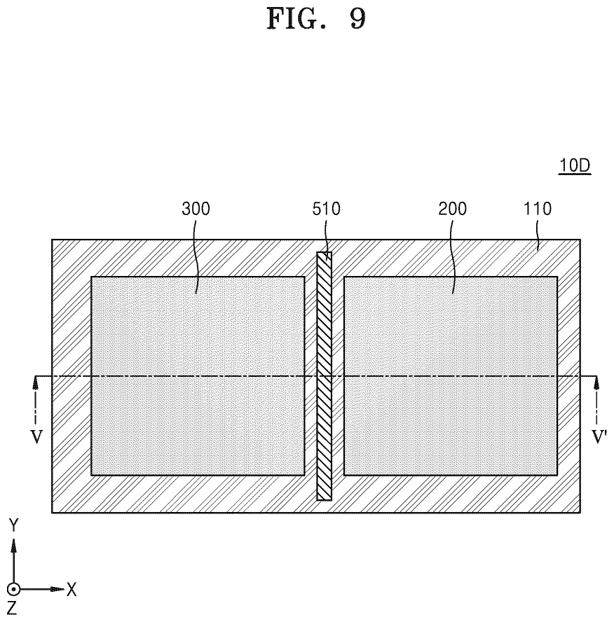

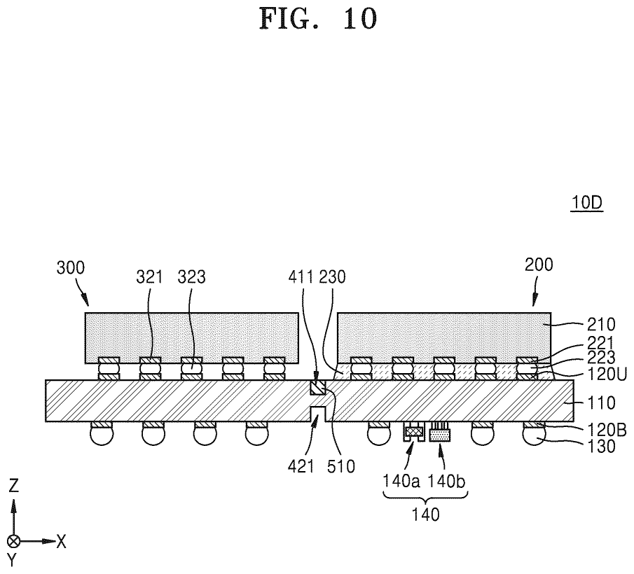

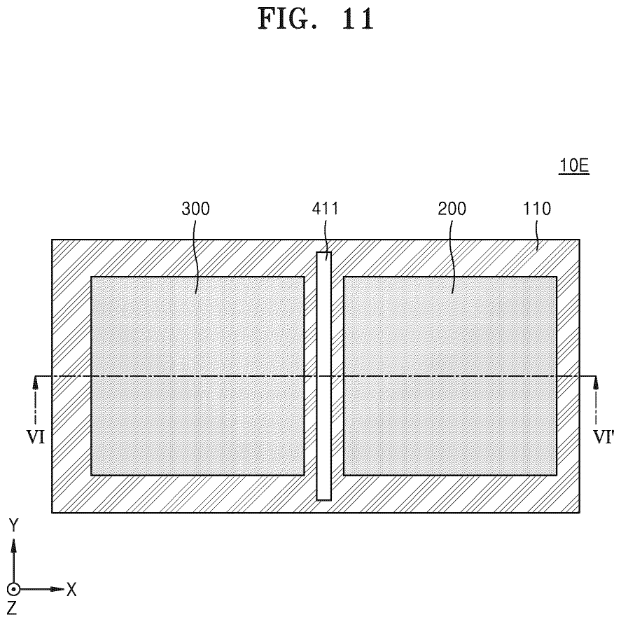

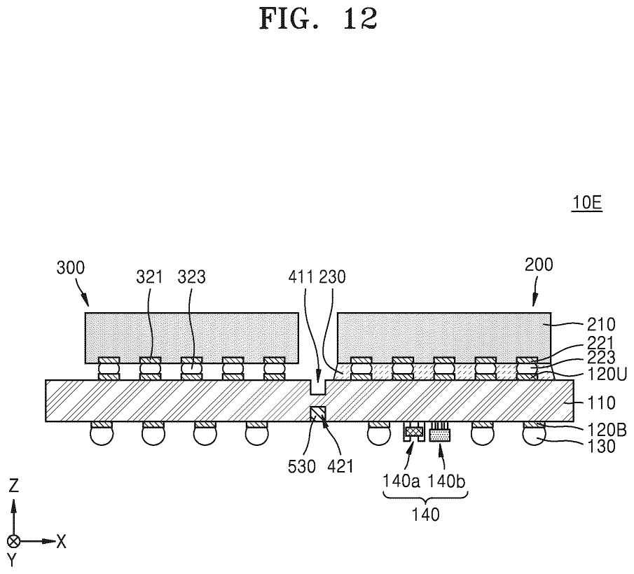

FIG. 5 is a plan view schematically showing a semiconductor package 10B according to an embodiment. FIG. 6 is a cross-sectional view of the semiconductor package 10B taken along line III-III′ of FIG. 5. FIG. 7 is a plan view schematically showing a semiconductor package 10C according to an embodiment. FIG. 8 is a cross-sectional view of the semiconductor package 10C taken along line IV-IV′ of FIG. 7. FIG. 9 is a plan view schematically showing a semiconductor package 10D according to an embodiment. FIG. 10 is a cross-sectional view of the semiconductor package 10D taken along line V-V′ of FIG. 9. FIG. 11 is a plan view schematically showing a semiconductor package 10E according to an embodiment. FIG. 12 is a cross-sectional view of the semiconductor package 10E taken along line VI-VI′ of FIG. 11. Hereinafter, repeated descriptions of the semiconductor packages 10 and 10A as those given with reference to FIGS. 1 to 4 may be omitted or simplified. The same reference numerals are given to the same elements.

Referring to FIG. 5 and FIG. 6, the semiconductor package 10B according to an embodiment may include a plurality of trenches and the second upper molding portion 520. The plurality of trenches may include the second upper portion 412 of the upper trench 410 and the second lower portion 422 of the lower trench 420. The second upper portion 412 of the upper trench 410, the second lower portion 422 of the lower trench 420, and the second upper molding portion 520 may be located on a side of the second semiconductor device 300.

The upper trench 410 of the semiconductor package 10B according to an embodiment may include the second upper portion 412 located close to the second side surface of the second semiconductor device 300 on the opposite side from the first semiconductor device 200. The second upper portion 412 may be spaced apart from the second side surface of the second semiconductor device 300 on the substrate 110 and may extend parallel to the second side surface thereof. For example, the second upper portion 412 may be spaced apart from the second side surface of the second semiconductor device 300 in the first horizontal direction (the X direction) and may extend in the second horizontal direction (the Y direction). The second upper portion 412 may be formed so as not to overlap the second semiconductor device 300 in the vertical direction (the Z direction). For example, the second upper portion 412 may be spaced apart from the second semiconductor device 300 in the vertical direction (the Z direction).

The second lower portion 422 may be disposed on the lower surface of the substrate 110 so as to face the second upper portion 412. The second lower portion 422 may be formed symmetrically with the second upper portion 412 about the substrate 110. The second upper portion 412 may have a shape recessed downward from the upper surface of the substrate 110 in the thickness direction of the substrate 110 and may extend in the second horizontal direction (the Y direction). Also, the second lower portion 422 may have a shape recessed upward from the lower surface of the substrate 110 in the thickness direction of the substrate 110 and may extend in the second horizontal direction (the Y direction). The second lower portion 422 may be formed in the lower surface of the substrate 110 so as not to overlap the plurality of external connection terminals 130. For example, the second lower portion 422 may be formed in the lower surface of the substrate 110 and spaced apart from the plurality of external connection terminals 130.

The second upper molding portion 520 may be formed in the second upper portion 412. For example, the second upper molding portion 520 may be formed in the second upper portion 412 and may not be formed on another portion. For example, the second upper molding portion 520 may fill the second upper portion 412 and may not fill another portion.

Referring to FIG. 7 and FIG. 8, the semiconductor package 10C according to an embodiment may include one or more trenches and the second lower molding portion 540. The trenches may include the second upper portion 412 of the upper trench 410 and the second lower portion 422 of the lower trench 420. The second upper portion 412 of the upper trench 410, the second lower portion 422 of the lower trench 420, and second lower molding portion 540 may be located on a side of the second semiconductor device 300.

Similar to the semiconductor package 10B of FIG. 5 and FIG. 6, the semiconductor package 10C according to an embodiment may include the second upper portion 412 as the upper trench 410 and the second lower portion 422 as the lower trench 420. However, according to an embodiment, the second lower molding portion 540 may be formed in the second lower portion 422. For example, the second lower molding portion 540 may fill the second lower portion 422 and may not be formed on another portion.

Referring to FIG. 9 and FIG. 10, the semiconductor package 10D according to an embodiment may include a plurality of trenches and the first upper molding portion 510. The plurality of trenches may include the first upper portion 411 of the upper trench 410 and the first lower portion 421 of the lower trench 420. The first upper portion 411 of the upper trench 410, the first lower portion 421 of the lower trench 420, and the first upper molding portion 510 may be located on a side of the second semiconductor device 300.

The upper trench 410 of the semiconductor package 10D according to an embodiment may include the first upper portion 411 located close to the first side surface of the second semiconductor device 300 adjacent to the first semiconductor device 200.

The first upper portion 411 may be spaced apart from the first side surface of the second semiconductor device 300 on the substrate 110 and may extend parallel to the first side surface thereof. For example, the first upper portion 411 may be spaced apart from the first side surface of the second semiconductor device 300 in the first horizontal direction (the X direction) and may extend in the second horizontal direction (the Y direction). The first upper portion 411 may be formed in the substrate 110 so as not to overlap the first semiconductor device 200 and the second semiconductor device 300 in the vertical direction (the Z direction). For example, the first upper portion 411 may be formed in the substrate 110 and spaced apart from the first semiconductor device 200 and the second semiconductor device 300 in the vertical direction (the Z direction).

The first lower portion 421 may be disposed in the lower surface of the substrate 110 to face the first upper portion 411. The first lower portion 421 may be formed symmetrically with the first upper portion 411 about the substrate 110. For example, the first upper portion 411 may have a shape recessed downward from the upper surface of the substrate 110 in the thickness direction of the substrate 110 and may extend in the second horizontal direction (the Y direction). Also, the first lower portion 421 may have a shape recessed upward from the lower surface of the substrate 110 in the thickness direction of the substrate 110 and may extend in the second horizontal direction (the Y direction). The first lower portion 421 may be formed in the lower surface of the substrate 110 so as not to overlap the plurality of external connection terminals 130. For example, the first lower portion 421 may be formed in the lower surface of the substrate 110 and spaced apart from the plurality of external connection terminals 130.

The first upper molding portion 510 may be formed in the first upper portion 411. The first upper molding portion 510 may be formed in the first upper portion 411 and may not be formed on another portion. The first upper molding portion 510 may fill the first upper portion 411 and may not fill another portion.

Referring to FIG. 11 and FIG. 12, the semiconductor package 10E according to an embodiment may include a plurality of trenches. The plurality of trenches may include the first upper portion 411 of the upper trench 410 and the first lower portion 421 of the lower trench 420. The first upper portion 411 of the upper trench 410, the first lower portion 421 of the lower trench 420, and the first lower molding portion 530 may be located on a side of the second semiconductor device 300.

Similar to the semiconductor package 10D of FIG. 9 and FIG. 10, the semiconductor package 10E according to an embodiment may include the first upper portion 411 as the upper trench 410 and the first lower portion 421 as the lower trench 420. However, according to an embodiment, the first lower molding portion 530 may be formed in the first lower portion 421 and may not be formed in the first upper portion 411.

FIGS. 1 to 12 illustrate that the upper trench 410 and the lower trench 420 have the same width, but embodiments are not limited thereto. The semiconductor package may include an upper trench 410 and a lower trench 420 having different widths. FIGS. 1 to 12 illustrate that the upper trench 410 and the lower trench 420 corresponding to the upper trench 410 may be formed as a set, but embodiments are not limited thereto. Also, FIGS. 1 to 12 illustrate that the trench 400 and the molding portion 500 may be formed on the first side and the second side of the second semiconductor device 300, that is, on opposite sides of the second semiconductor device 300 in the first horizontal direction (the X direction), but embodiments are not limited thereto.

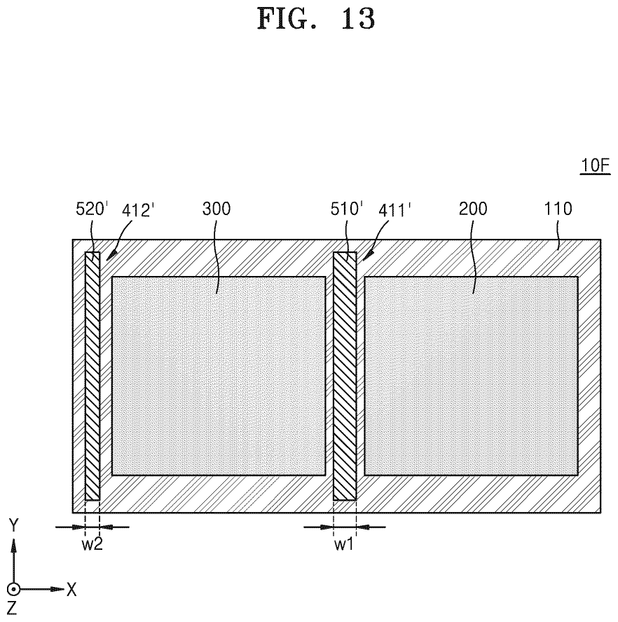

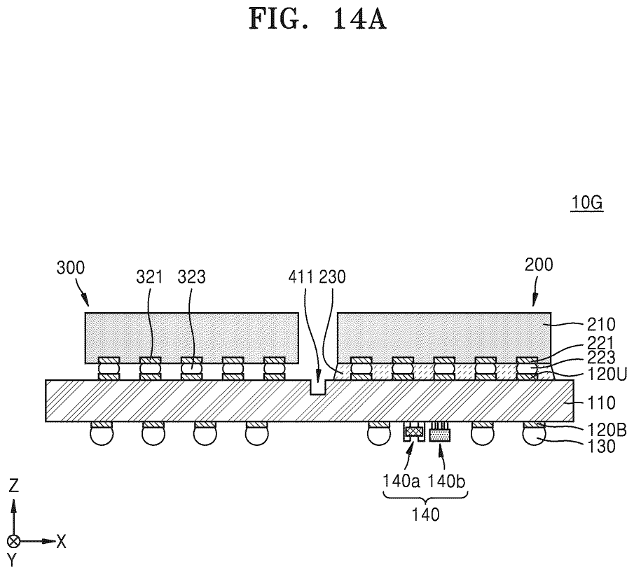

FIG. 13 is a plan view schematically showing a semiconductor package 10F according to an embodiment.

Referring to FIG. 13, the semiconductor package 10F according to an embodiment may include a first upper portion 411′ and a second upper portion 412′ having different widths.

The first upper portion 411′ may be located at the first side surface, adjacent to the first semiconductor device 200, among the side surfaces of the second semiconductor device 300. The first upper portion 411′ may be spaced apart from the first side surface of the second semiconductor device 300 on the substrate 110 and may extend parallel to the first side surface thereof. The second upper portion 412′ may be located at the second side surface, opposite to the first semiconductor device 200, among the side surfaces of the second semiconductor device 300. The second upper portion 412′ may be spaced apart from the second side surface of the second semiconductor device 300 on the substrate 110 and may extend parallel to the second side surface thereof. Herein, a width w1 of the first upper portion 411′ in the first horizontal direction (the X direction) may be greater than a width w2 of the second upper portion 412′. Accordingly, the width of a first upper molding portion 510′ applied into the first upper portion 411′ may be greater than the width of a second upper molding portion 520′ applied into the second upper portion 412′.

FIG. 13 illustrates that the width w1 of the first upper portion 411′ is greater than the width w2 of the second upper portion 412′, but embodiments are not limited thereto. In order to control the warpage of the semiconductor package, a trench and a molding portion having a larger width may be formed in a region that requires a greater increase in rigidity.

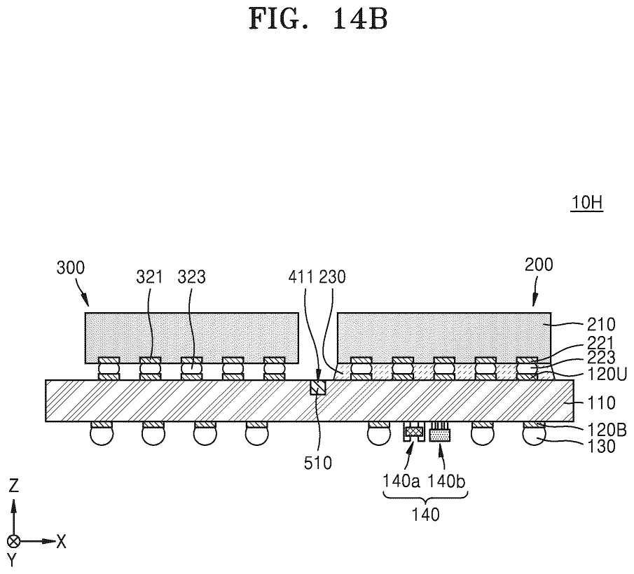

FIG. 14A and FIG. 14B are cross-sectional views schematically showing semiconductor packages 10G and 10H according to an embodiment.

Referring to FIG. 14A, the semiconductor package 10G according to an embodiment may include the first upper portion 411 formed in the upper surface of the substrate 110. For example, a first lower portion 421 corresponding to the first upper portion 411 may be omitted. The semiconductor package 10G according to an embodiment may include, as the upper trench 410, the first upper portion 411 maybe located close to the first side surface of the second semiconductor device 300 adjacent to the first semiconductor device 200. However, according to an embodiment, the first lower portion 421 corresponding to the first upper portion 411 may be omitted. In this case, the semiconductor package 10G may not include a molding portion, and the first upper portion 411 may be formed as a groove in the upper surface of the substrate 110 and the flexural rigidity on the upper surface of the substrate 110 may be reduced and a warpage may be controlled. For example, a convex warpage may be inhibited or prevented in which a central portion of the substrate 110 may lift higher than edge portions thereof.

Referring to FIG. 14B, the semiconductor package 10H according to an embodiment may further include the first upper molding portion 510 in addition to the semiconductor package 10G of FIG. 14A. The semiconductor package 10H according to an embodiment may not include a trench remaining as a groove. However, the flexural rigidity on the upper surface of the substrate 110 may be increased by the first upper molding portion 510, which may control warpage. For example, a concave warpage may be inhibited or prevented in which edge portions of the substrate 110 lift higher than a central portion thereof.

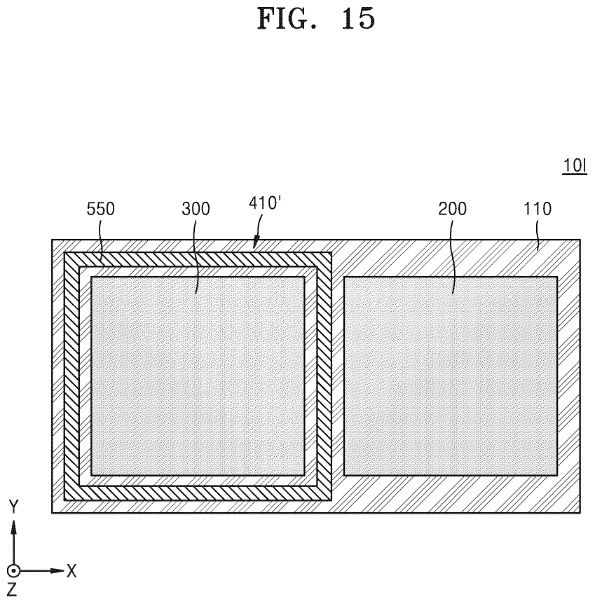

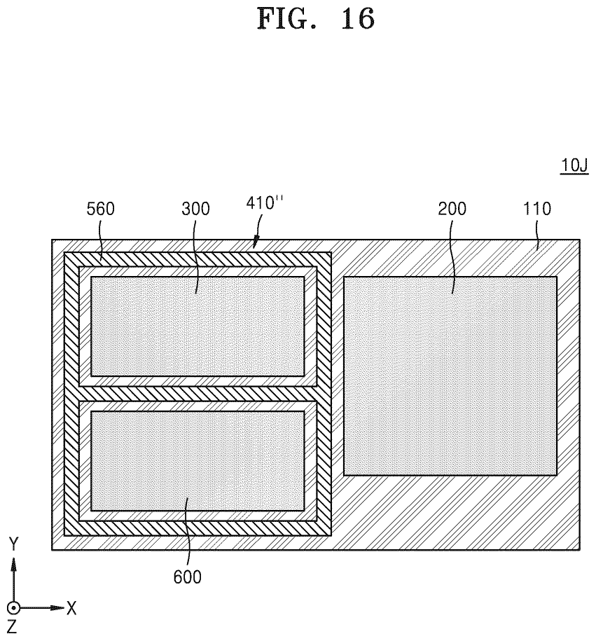

FIG. 15 is a plan view schematically showing a semiconductor package 10I according to an embodiment.

Referring to FIG. 15, the semiconductor package 10I according to an embodiment may include an upper trench 410′ at side surfaces of the second semiconductor device 300. For example, the semiconductor package 10I according to an embodiment may include an upper trench 410′ surrounding four side surfaces of the second semiconductor device 300. Sides of the upper trench 410′ may be respectively spaced apart from side surfaces of the second semiconductor device 300. The semiconductor package 10I may include a molding portion 550 formed in the inner space of the upper trench 410′. For example, the molding portion 550 may fill the inner space of the upper trench 410′. Although not shown, the semiconductor package 10I may include a lower trench formed in the lower surface of the substrate 110 and symmetrical to the upper trench 410′.

FIGS. 1 to 15 illustrate a case in which each trench 400 may be disposed at one side, two opposing sides, or all sides of the second semiconductor device 300, but embodiments are not limited thereto. For example, the trench 400 may surround three sides of the second semiconductor device 300, while exposing at least one other side of the second semiconductor device 300.

FIG. 16 is a plan view schematically showing a semiconductor package 10J according to an embodiment.

Referring to FIG. 16, the semiconductor package 10J according to an embodiment may further include a third semiconductor device 600. The third semiconductor device 600 may be disposed on the substrate 110, spaced apart from the first semiconductor device 200 in the first horizontal direction (the X direction), and spaced apart from the second semiconductor device 300 in the second horizontal direction (the Y direction). The semiconductor package 10J according to an embodiment may include an upper trench 410″ formed in the upper surface of the substrate 110 around at least a portion of the third semiconductor device 600 and a lower trench (not shown) formed in the lower surface of the substrate 110 may have a shape symmetrical to the upper trench 410″. For example, the upper trench 410″ may be formed in the upper surface of the substrate 110 surrounding the third semiconductor device 600, and the lower trench (not shown) formed in the lower surface of the substrate 110 may have a shape symmetrical to the upper trench 410″. In addition, an upper molding portion 560 may be provided so as to fill the upper trench 410″.

FIG. 16 illustrates that the semiconductor package 10J may include a first semiconductor device 200, a second semiconductor device 300, and a third semiconductor device 600, and the upper trench 410″ surrounds the second semiconductor device 300 and the third semiconductor device 600, but embodiments are not limited thereto. The semiconductor package may include two or more semiconductor devices and be modified in various ways so that a trench and a molding portion may be formed adjacent to one to all side surfaces of each of the semiconductor devices except for the first semiconductor device 200.

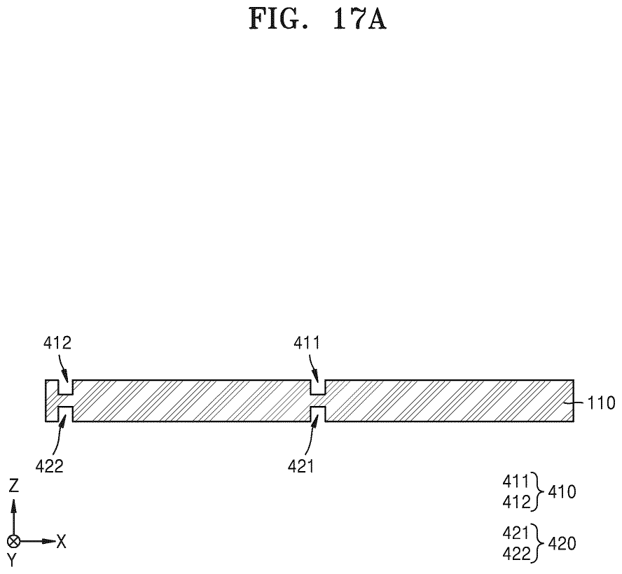

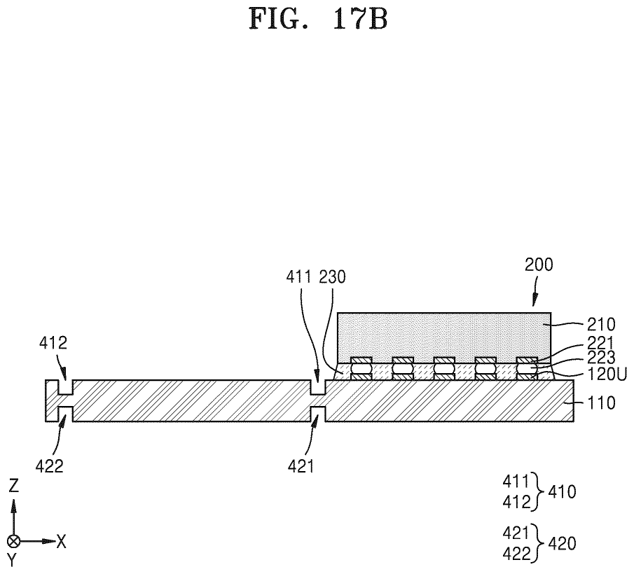

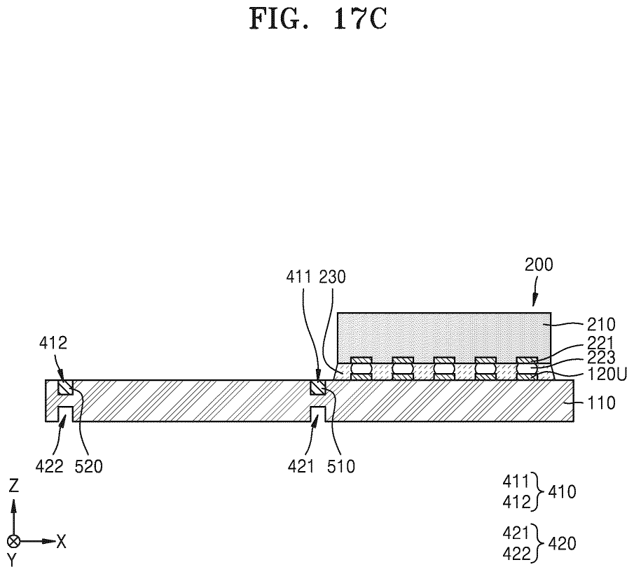

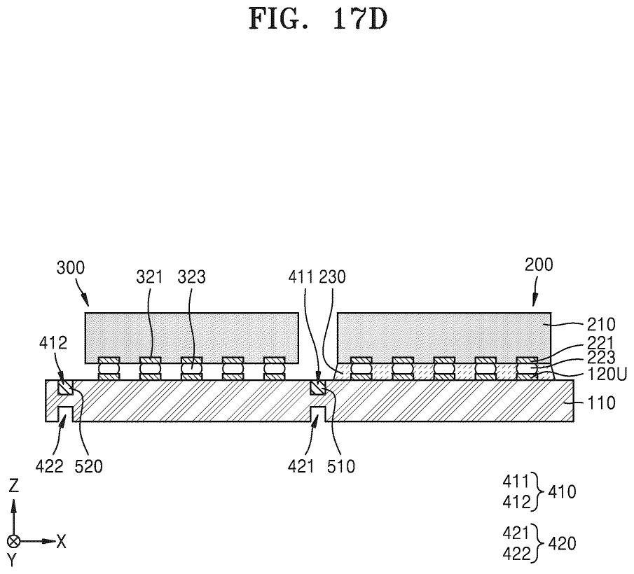

FIGS. 17A to 17D are diagrams showing a process of manufacturing a semiconductor package, according to an embodiment.

Referring to FIG. 17A and FIG. 17B, an upper trench 410 and a lower trench 420 may be formed in the substrate 110, considering the arrangement of a first semiconductor device 200 and a second semiconductor device 300. Subsequently, the first semiconductor device 200 may be mounted on the substrate 110.

Referring to FIG. 17C and FIG. 17D, a first upper molding portion 510 and a second upper molding portion 520 may be formed in a first upper portion 411 and a second upper portion 412 of the upper trench 410, respectively. Subsequently, the second semiconductor device 300 may be mounted on the substrate 110.

FIGS. 17A to 17D illustrate a method of manufacturing a semiconductor package, according to an embodiment. A process order may be changed. For example, the upper trench 410 and the lower trench 420 may be formed in a state in which the first semiconductor device 200 is mounted on the substrate 110, and the second semiconductor device 300 may be mounted after the first upper molding portion 510 and the second upper molding portion 520 are formed.

While the inventive concept has been particularly shown and described with reference to embodiments thereof, it will be understood that various changes in form and details may be made therein without departing from the spirit and scope of the following claims.

What is claimed is:

1. A semiconductor package comprising:
a substrate;
a first semiconductor device disposed on the substrate;
a second semiconductor device disposed on the substrate and spaced apart from the first semiconductor device in a horizontal direction;
an upper trench formed in an upper surface of the substrate at a side of the second semiconductor device;
a lower trench formed in a lower surface of the substrate; and
a molding portion disposed in the upper trench.

2. The semiconductor package of claim 1, wherein the lower trench has a shape symmetrical to the upper trench, and the lower trench overlaps the upper trench in a vertical direction with a portion of the substrate disposed therebetween.

3. The semiconductor package of claim 1, wherein the upper trench extends parallel to the side of the second semiconductor device.

4. The semiconductor package of claim 1, wherein the upper trench comprises a first upper portion spaced apart in the horizontal direction from a first side surface, among four side surfaces of the second semiconductor device, adjacent to the first semiconductor device and extending parallel to the first side surface of the second semiconductor device, and
the lower trench comprises a first lower portion disposed in the lower surface of the substrate to face the first upper portion of the upper trench.

5. The semiconductor package of claim 1, wherein the upper trench comprises a second upper portion spaced apart in the horizontal direction from a second side surface, among four side surfaces of the second semiconductor device, opposite to the first semiconductor device and extending parallel to the second side surface of the second semiconductor device, and
the lower trench comprises a second lower portion disposed in the lower surface of the substrate to face the second upper portion of the upper trench.

6. The semiconductor package of claim 1, wherein the upper trench comprises:
a first upper portion spaced apart in the horizontal direction from a first side surface, among four side surfaces of the second semiconductor device, adjacent to the first semiconductor device and extending parallel to the first side surface of the second semiconductor device; and
a second upper portion spaced apart in the horizontal direction from a second side surface opposite to the first side surface of the second semiconductor device and extending parallel to the second side surface of the second semiconductor device, and
wherein the lower trench comprises a first lower portion and a second lower portion disposed in the lower surface of the substrate to face the first upper portion and the second upper portion of the upper trench, respectively, and
the molding portion comprises a first molding portion and a second molding portion disposed in the first upper portion and the second upper portion of the upper trench, respectively.

7. The semiconductor package of claim 6, wherein a width of the first upper portion of the upper trench is different from a width of the second upper portion of the upper trench.

8. The semiconductor package of claim 1, wherein the upper trench surrounds side surfaces of the second semiconductor device.

9. The semiconductor package of claim 1, wherein the upper trench extends longer than a length of a side surface of the second semiconductor device adjacent to the upper trench.

10. The semiconductor package of claim 1, wherein a depth of the upper trench and a depth of the lower trench each are less than or equal to ⅓ of a thickness of the substrate.

11. The semiconductor package of claim 1, wherein the molding portion comprises a material having a coefficient of thermal expansion and a modulus of elasticity greater than a coefficient of thermal expansion and a modulus of elasticity of the substrate.

12. The semiconductor package of claim 1, wherein the molding portion fills the upper trench and a thickness of the molding portion is greater than or equal to a depth of the upper trench.

13. The semiconductor package of claim 1, wherein the upper trench is formed in the upper surface of the substrate and spaced apart from the first semiconductor device and the second semiconductor device in a vertical direction.

14. The semiconductor package of claim 1, wherein a plurality of external connection terminals are arranged on the lower surface of the substrate, and
the lower trench is formed in the lower surface of the substrate and spaced apart from the plurality of external connection terminals.

15. A semiconductor package comprising:
a substrate;
a first semiconductor device disposed on the substrate;
a second semiconductor device disposed on the substrate and spaced apart from the first semiconductor device in a horizontal direction;
an upper trench formed in an upper surface of the substrate at a side of the second semiconductor device;
a lower trench formed in a lower surface of the substrate; and
a molding portion disposed in the lower trench.

16. The semiconductor package of claim 15, wherein the lower trench has a shape symmetrical to the upper trench, and the lower trench overlaps the upper trench in a vertical direction with a portion of the substrate disposed therebetween.

17. The semiconductor package of claim 15, wherein the upper trench extends parallel to one side surface of the second semiconductor device.

18. The semiconductor package of claim 15, wherein the upper trench extends longer than a length of the side of the second semiconductor device adjacent to the upper trench.

19. The semiconductor package of claim 15, wherein the molding portion comprises a material having a coefficient of thermal expansion and a modulus of elasticity greater than a coefficient of thermal expansion and a modulus of elasticity of the substrate.

20. A semiconductor package comprising:
a substrate;
a plurality of external connection terminals arranged on a lower surface of the substrate;
a passive device disposed on the lower surface of the substrate;
a first semiconductor device disposed on the substrate;
a second semiconductor device disposed on the substrate and spaced apart from the first semiconductor device in a horizontal direction;
an upper trench formed in an upper surface of the substrate;
a lower trench having a shape symmetrical to the upper trench and formed in the lower surface of the substrate to overlap the upper trench in a vertical direction and not to overlap the plurality of external connection terminals; and
a molding portion configured to fill an inner space of the upper trench and comprising a material having a coefficient of thermal expansion and a modulus of elasticity greater than a coefficient of thermal expansion and a modulus of elasticity of the substrate,
wherein the upper trench is adjacent to a side surface of the second semiconductor device, is parallel to the side surface of the second semiconductor device, and extends longer than a length of the side surface of the second semiconductor device, and
a depth of the upper trench and a depth of the lower trench each are less than or equal to ⅓ of a thickness of the substrate.
